(19) United States
(12) Patent Application Publication
(10) Pub. No.: US 2012/0126116 A1
(43) Pub. Date: May 24, 2012

(54) PATTERN SHAPE SELECTION METHOD AND PATTERN MEASURING DEVICE

(75) Inventors: Maki Tanaka, Yokohama (JP); Chie Shishido, Kawasaki (JP); Wataru Nagatomo, Yokohama (JP); Mayuka Osaki, Yokohama (JP)

(73) Assignee: HITACHI HIGH-TECHNOLOGIES CORPORATION, Tokyo (JP)

(21) Appl. No.: 13/387,944

(22) PCT Filed: Jul. 15, 2010
(86) PCT No.: PCT/JP2010/004587

§ 371 Date: Jan. 30, 2012

(30) Foreign Application Priority Data
Jul. 31, 2009 (JP) 2009-178577

(51) Int. Cl. H01J 37/26

(52) U.S. Cl. 250/307; 250/310

(57) ABSTRACT

The present invention has an object to propose a method and an apparatus for selecting a pattern shape, wherein, when estimating a shape based on comparison between an actual waveform and a library, the method and the apparatus can appropriately estimate the shape. As an embodiment to achieve the object, a method and an apparatus for selecting a pattern shape by comparing an obtained shape with pattern shapes memorized in the library are proposed, wherein plural pieces of waveform information are obtained under a plurality of waveform acquiring conditions based on radiation of a charged particle beam onto a specimen; and a pattern shape memorized in the library is selected by referring, with respect to the plural pieces of waveform information, to a library memorizing plural pieces of waveform information acquired under different waveform acquiring conditions for each of a plurality of pattern shapes.

### TECHNICAL FIELD

The present invention relates to a method and an apparatus for measuring dimensions of a pattern formed on a specimen, and in particular, to a method and an apparatus for appropriately selecting an acquiring condition of an image to be acquired to identify a shape of a pattern or to measure dimensions thereof.

### BACKGROUND ART

In the semiconductor wafer production process, multilayer patterns formed on a wafer are rapidly becoming finer; hence, the process monitor to monitor whether or not these patterns are formed on the wafer according to designs thereof is increasingly important. Particularly, wiring patterns including transistor gate wiring are deeply associated with their linewidths and device operation characteristics; hence, the monitoring of the wiring production process is especially important.

As a length measuring tool to measure a linewidth of fine wiring on the order of several tens of nanometers, there has been conventionally employed a SEM (Scanning Electron Microscope) to measure the linewidth (Critical Dimension Scanning Electron Microscope), the SEM being capable of taking an image of lines at several hundreds of thousands-fold magnification. Patent Literature 1 describes an example of a length measuring process using such scanning electron microscope. Patent Literature 1 discloses a scheme for averaging signal profiles of the wiring in a longitudinal direction of the wiring on a local area in a taken image of wiring to be measured, to create a projection profile; and the right and left wiring edges are detected in the profile to calculate the wiring dimension from the distance between the edges.

However, as disclosed in Nonpatent Literature 1 (FIG. 1), as for an SEM signal waveform, it has been known that, when a shape to be measured changes, the signal waveform also changes according thereto. As the semiconductor pattern becomes finer, these measuring errors increasingly affect the process monitor. Nonpatent Literatures 1 and 2 disclose a scheme for reducing such measuring errors. According to the scheme, the relationship between a pattern shape and an SEM signal waveform is beforehand calculated through simulation; high-precision measurement is implemented independently of the target shape using the calculation results.

Specifically, according to the scheme disclosed in Nonpatent Literatures 1 and 2, the relationship between a pattern shape and an SEM signal waveform is beforehand calculated through SEM simulation to implement high-precision measurement independently of the shape to be measured by use of the result. Nonpatent Literatures 1 and 2 disclose a scheme for correctly estimating the shape and dimensions by obtaining parameters of a digitized pattern shape and storing SEM simulation results for various shapes as a library to compare the library with actual waveforms.

### CITATION LIST

### Patent Literature

PATENT LITERATURE 1: JP-A-11-316115

### Nonpatent Literature

NONPATENT LITERATURE 1: J. S. Villarrubia, A. E. Vladar, J. R. Lowney, and M. T. Postek, “Scanning electron microscope analog of scatterometry”, Proc. SPIE 4689, pp. 304-312 (2002)
NONPATENT LITERATURE 2: J. S. Villarrubia, A. E. Vladar, M. T. Postek, “A simulation study of repeatability and bias in the CD-SEM”, Proc. SPIE 5038, pp. 138-149, 2003.

### SUMMARY OF INVENTION

### Technical Problem

If the library as described above is employed, the use of a charged particle beam apparatus represented by a scanning electron microscope enables estimating a pattern shape based on an obtained signal waveform; however, through the comparison between a waveform memorized in the library and a waveform obtained on the basis of the actual measurement, the pattern shape cannot be uniquely determined in some cases. Also, even for a different pattern shape under a certain waveform acquiring condition, the waveform little varies and it is hence difficult to identify the pattern shape. In Patent Literature 1 as well as Nonpatent Literatures 1 and 2, such problem and the solution thereto have not been discussed at all.

Description will be given below of a pattern shape selection method, a measuring method, and a charged particle beam apparatus for appropriately estimating a shape even if it is difficult to estimate the pattern shape acquired under a certain condition when estimating a shape based on comparison between an actual waveform and a library. Also, description will be additionally given of a method and an apparatus for selecting an optimal image acquiring condition in a charged particle beam apparatus.

### Solution to Problem

As an embodiment to achieve the above object, a method and an apparatus for selecting a pattern shape by referring to a library with respect to an acquired waveform are proposed, wherein waveform information is acquired under a plurality of waveform acquiring conditions based on radiation of a charged particle beam onto a specimen; and a pattern shape memorized in the library is selected by referring, with respect to plural pieces of the waveform information, to a library memorizing waveform information acquired under different waveform acquiring conditions for each of a plurality of pattern shapes.

### Advantageous Effects of Invention

According to the above embodiment, a pattern shape can be selected based on a plurality of waveform acquiring conditions; hence, even if it is difficult to identify a pattern shape under a certain waveform acquiring condition, the pattern shape can be uniquely selected and high-precision pattern shape estimation can be implemented.

### BRIEF DESCRIPTION OF DRAWINGS

FIG. 1 is a flowchart to explain a process to create a library for estimating a pattern shape and a process to estimate a pattern shape by referring to the library.

FIG. 2 is a diagram to explain that an obtained waveform changes depending on an electron detecting condition.

FIG. 3 is a diagram to explain that a signal waveform changes depending on an image acquiring condition.

FIG. 4 is a diagram to explain an outline of a scanning electron microscope.

FIG. 5 is a flowchart to explain a library matching process.

FIG. 6 is a diagram to explain an outline of the library and the library matching.

FIG. 7 is a diagram to explain an outline of calculation of an overall noncoincidence degree in the library matching.

FIG. 8 is a diagram to explain an outline of consistency evaluation for the noncoincidence degree calculation results of the library matching.

FIG. 9 is a flowchart to explain a process to determine an image acquiring condition of a scanning electron microscope based on library data and a process to estimate a pattern shape based on the library matching.

FIG. 10 is a diagram to explain a relationship between a pattern shape and an obtained waveform.

### DESCRIPTION OF EMBODIMENTS

In the description below, a scheme for registering a waveform for each pattern shape to carry out pattern shape estimation and measurement based on actual measurement will be called a model-based measurement or library matching scheme. For this matching processing with the library, various nonlinear optimization schemes can be employed. However, in such estimation schemes, a correct result cannot be easily obtained if stability for the solution cannot be obtained.

As described in M. Tanaka, J. S. Villarrubia and A. E. Vladar, “Influence of Focus Variation on Linewidth Measurements”, Proc. SPIE 5752, pp. 144-155 (2005), and M. Tanaka, J. Meessen, C. Shishido et al., “CD bias reduction in CD-SEM linewidth measurements for advanced lithography”, Proc. SPIE 6922, pp. 69221T-1-11 (2008), there exists a case where the solution cannot be uniquely determined in the library matching.

Moreover, there also exists a case where, depending on a combination of a pattern shape change and an SEM image acquiring condition, the SEM image little changes even when the pattern shape changes. For example, when a lower section of the pattern is thinner than an upper section thereof, clear difference does not appear in an image observed from just above. In such case, it is natural that the library matching is not appropriately conducted and a correct measurement result is not attainable.

To solve such problem, it is required to acquire an SEM image sensitive to the change in the pattern shape to be measured. Further, when the solution is not uniquely determined as described above, it is effective to add restraint conditions by adding some information. So, description will be given below of a scheme for improving the library matching precision by using and combining SEM images acquired under a plurality of different acquiring conditions. Combining a plurality of images (or waveforms) having different characteristics enables the more stable matching compared with the matching by use of images under only one condition.

A first embodiment evaluates the noncoincidence degrees between SEM images acquired under the different acquiring conditions and simulation images calculated under associated conditions for each image; calculates an overall noncoincidence degree through averaging processing to obtain a simulation pattern shape for which the overall noncoincidence degree is minimum; and measures the shape and the dimensions of the target pattern.

As a second embodiment, another method is disclosed, the method comprising: based on the noncoincidence degree between SEM images acquired under the different acquiring conditions and simulation images calculated under associated conditions, estimating a simulation pattern shape for which the noncoincidence degree takes the minimum value for each image acquiring condition; and, by comprehensively using a plurality of shape and dimension estimation results thus obtained, measuring the shape and the dimensions of the target pattern.

As a third embodiment, another method is disclosed, the method comprising: evaluating simulation waveforms under a plurality of different image conditions under which an SEM apparatus employed for the measurement can take an image; and selecting an image acquiring condition sensitive to a shape change.

According to the above schemes, the matching precision can be improved in the model-based measuring scheme; as a result, the precision of the model-based measuring scheme itself is also improved. Even for a pattern shape change for which the measurement has been difficult since sensitivity is not obtained by use of only one kind of images, the measurement sensitivity is improved and high-precision measurement becomes possible. In addition, combining images acquired under a plurality of conditions enables evaluating the reliability of shape estimation results to improve the error judgment ratio and the measurement reliability.

The above schemes are applicable to various charged particle beam apparatuses (an SEM, an ion microscope, etc.); however, in the following embodiments, description will be given of an example of employing an SEM as a representative.

### Embodiment 1

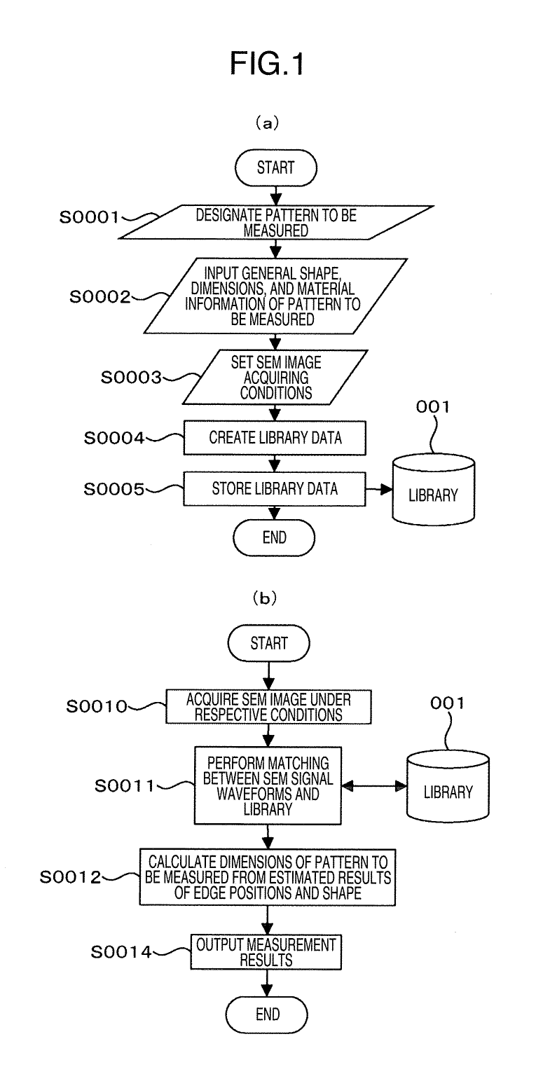

In the first embodiment, description will be given of a basic embodiment of a pattern dimension measuring method using SEM images acquired under a plurality of mutually different detecting conditions with reference to FIGS. 1 to 7.

FIG. 1 shows a procedure of the pattern dimension measuring method. According to the present invention, SEM images of a pattern to be measured are acquired under a plurality of different detecting conditions. By comparing a plurality of SEM images thus acquired with a simulation library which is calculated under the same detecting conditions and which is created in advance, the shape and the dimensions of the pattern to be measured are estimated.

The simulation library is a library: storing SEM simulation waveforms calculated by setting a pattern shape to various values with a relationship between the simulation waveforms and shape information thereof; executing matching processing to select from these SEM simulation waveforms a waveform having a shape most similar to an actual SEM image signal waveform; estimating the dimensions and the shape of the pattern to be measured from sample shape parameters at simulation waveform calculation and matching positions. If the image acquiring condition differs, a property of the SEM image differs even for the same sample. Hence, even if no difference between different pattern shapes appears in the SEM signal waveform of only images acquired under a certain condition, some differences can appear in images acquired under other conditions.

For example, in a case where a lower section of the pattern is thinner than an upper section thereof, clear difference does not appear in an image observed from just above compared with a perpendicular side wall; however, in an SEM image acquired in an inclined direction, the difference can be detected. In this case, even if the sensitivity to the change of pattern shape is not obtained by one conventional image, combining these images acquired under a plurality of different conditions enables estimating the shape and the dimensions of the pattern with high precision by conducting the matching. In this way, the high-precision pattern measurement is conducted by performing the matching by use of a plurality of images having different sensitivity to different shape.

FIG. 1(a) shows a procedure to create a simulation library and an image acquiring recipe (a file recording a procedure for automatic image acquisition in the form of an apparatus task list). First, a pattern to be measured is designated (step S0001). The pattern may be designated, by actually observing a pattern by an SEM, or by using pattern design data. Next, to create a simulation library used to measure the designated pattern, the operator inputs information of a general shape, dimensions, and material of the pattern to be measured (step S0002). This is input information to set a range of pattern shapes created in the simulation library and material parameters for simulation, and is set in advance to appropriate values according to a production process of the pattern to be measured. The materials, structure, target, allowable dimensions, etc. of the pattern are determined in the design stage; hence, if the pattern to be measured is determined, it is easy to set these values. In an environment accessible to these design information data, the values can also be automatically set based on the design data without any intervention of the operator. Or, naturally, the actual pattern may also be measured by a conventional Critical Dimension SEM, an AFM, or any other measuring scheme for determining general dimensions based on results of the measurement.

Next, an SEM image acquiring condition used for actual measurement is set (step S0003). Here, the SEM image acquiring condition indicates an amount of energy (acceleration voltage) or current of an electron beam radiated onto a specimen, a radiation speed or frequency, a radiation direction, energy or a direction of electrons to be detected, and an inclination angle of a specimen stage. Setting of the image acquiring condition will be described later in detail.

The image acquiring condition (waveform acquiring condition) mainly includes (1) an electron beam radiating condition of the scanning electron microscope (electron beam energy (energy arriving at the specimen)), an amount of radiation current of the electron beam, the size (magnification) of the scanning range (Field Of View: FOV), a beam inclination (stage inclination), etc., (2) an electron detecting condition (the type of the detector, presence or absence of energy filtering, etc.), (3) an image processing condition, (4) a specimen condition, and (5) a combination of at least two selected from (1) to (4). Among the conditions, the specimen condition of (4) is, for example, a pre-charge condition for the specimen. For the scanning electron microscope, there is a pre-charge technique called pre-doze or pre-charge; a plurality of signals under different conditions can be obtained by setting an image before pre-doze as an image of Condition A and setting an image acquired after pre-charge by an electron beam as an image of Condition B.

Further, when the energy arriving at the specimen is changed, the emission rate δ of secondary electrons emitted from the specimen changes and the image also change; hence, it is also possible that the waveforms before and after the change in the energy of the electron beam arriving at the specimen may be set respectively as a waveform obtained under Condition A and as a waveform obtained under Condition B. In addition, when the amount of radiation current and the scanning range are changed, the charged state due to the electron beam radiation and the image also change; hence, similarly, the image before the condition change may be set as a waveform under Condition A and the image after the condition change is set as a waveform under Condition B.

A plurality of appropriate waveform acquiring conditions are prepared according to pattern materials, pattern shapes, and the like to create the library based thereon, it enables correctly estimating a pattern shape.

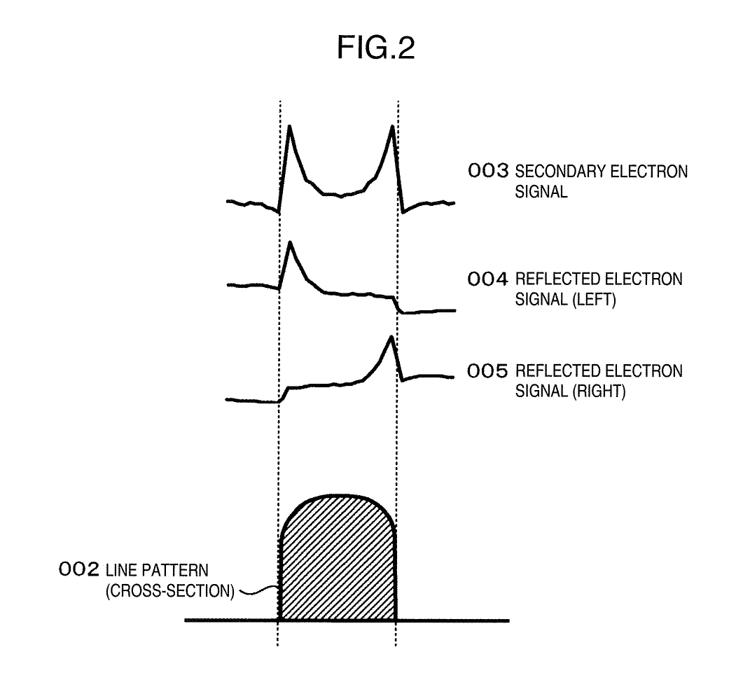

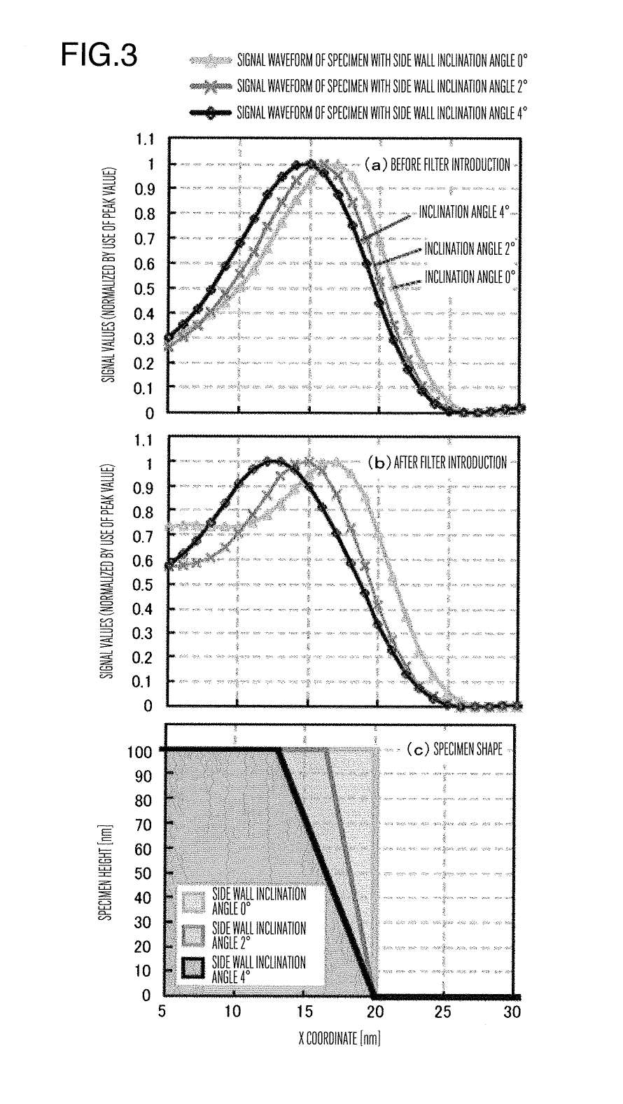

FIGS. 2 and 3 show an example of an image detected under different conditions. FIG. 2 shows an SEM signal waveform of a line pattern 002 having a certain cross-sectional shape. FIG. 2 shows signal waveforms obtained by detecting electrons of different energies and emission directions generated by radiating an electron beam onto a specimen surface. 003 indicates a secondary electron signal image acquired by detecting secondary electrons having relatively low energy in which the amount of signals increases in edge sections of the pattern. On the other hand, waveforms obtained by detecting reflected electrons having relatively high energy by detectors disposed at the upper-left and the upper-right of the specimen are reflected electrons (left) 0004 and reflected electrons (right) 0005, respectively. For the reflected electron signal, since a detector detects more electrons emitted on the side where the detector is disposed, the detector on the left side detects more signals from the left side wall section and the detector on the right side detects more signals from the right side wall section. In this way, due to the electrons generated by the electron beam radiation, the obtained signal waveform changes according to the energy and the direction thereof. Further, FIG. 3 shows another discussion example of simulation conducted by the inventors (disclosed in M. Tanaka, J. Meessen, C. Shishido et al., “CD bias reduction in CD-SEM linewidth measurements for advanced lithography”, Proc. SPIE 6922, pp. 69221T-1-11 (2008)). FIG. 3 shows a change in a signal waveform when the electron energy to be detected is changed, and it can be seen that, if the shape changes among three different kinds of side wall shape patterns as shown in FIG. 3 (c), the change of the signal waveform differs between (a) when signals of all energy emitted are detected and (b) when only electrons having high energy are detected. Like these, even for the same sample, the obtained SEM signal waveform changes when the electron detecting condition changes; hence a different image sensitivity to difference to be detected (for example, difference in the side wall inclination angle) can be obtained.

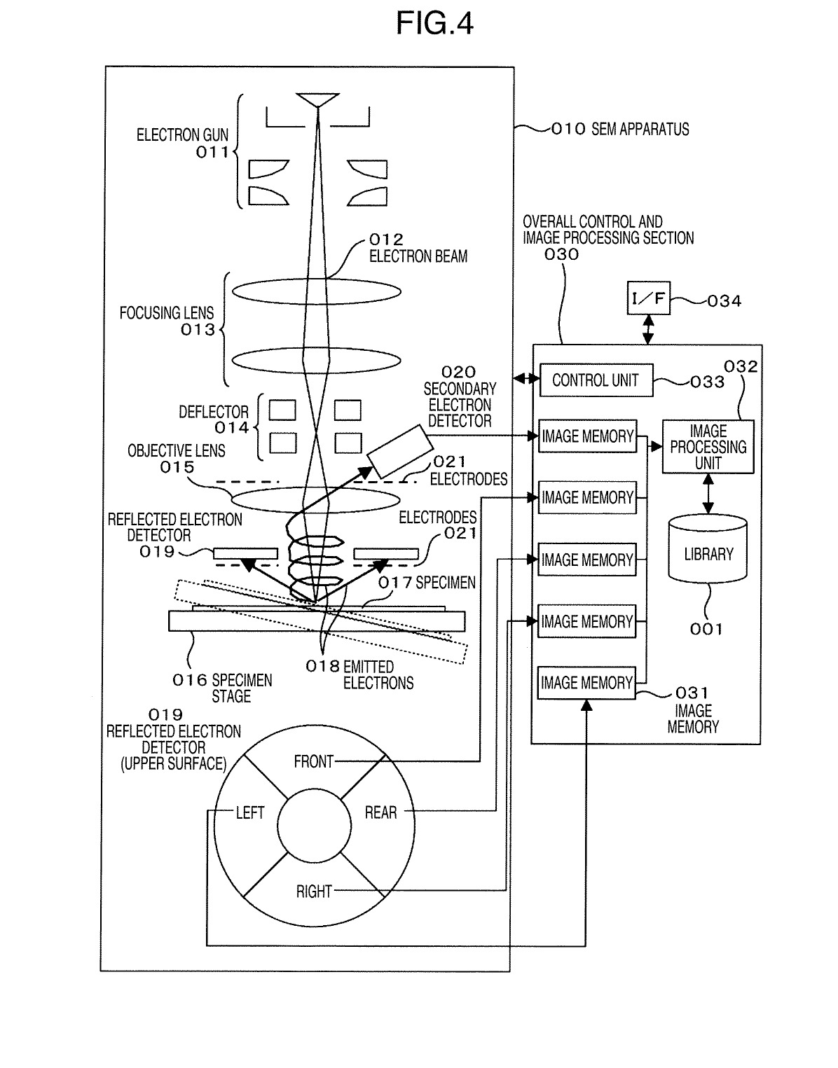

As well as the electron detecting conditions shown in FIGS. 3 and 4, even if an amount of the energy (acceleration voltage) or current, a radiation speed or frequency, a radiation angle, or the like of the electron beam is changed, the obtained signal waveform changes according to respective characteristics. In step S0003 of FIG. 1, a plurality of such image acquiring conditions are set in advance.

Next, for combinations of the information of the general shape, dimensions, and material of the pattern to be measured set in step S0002 and SEM image acquiring conditions set in step S0003, the SEM signal waveform simulation is conducted to create the simulation library data (step S0004). These simulation results, the image acquiring conditions, and the pattern shape information are combined to be stored as the simulation library data (step S0005). Through the above procedure, a plurality of SEM image acquiring recipes and the simulation library are created to be used for measurement.

Incidentally, the pattern shape information may actually be not only acquired based on the simulation, but also extracted based on the image information of a cross-sectional image of the pattern acquired by an SEM or beforehand acquired by an apparatus such as an Atomic Force Microscope (AFM). As far as, in the library, a plurality of waveform acquiring information and pattern shape information are memorized with a relationship therebetween and a pattern shape can be estimated through comparison between waveforms obtained under a plurality of waveform acquiring conditions, sources of pattern shape information are not considered.

In this way, in order to create a library by use of actual patterns, it is preferable to use patterns of as various shapes or dimensions as possible. For example, in the exposure process, a wafer called Focus-Exposure Matrix may be created. This process creates patterns in which the exposure energy and the exposure focus condition are changed for each exposure shot; it is possible to easily create various shape patterns which may appear in an actual production process. Also for an etching pattern, etching by using the Focus-Exposure Matrix as a mask can increase variations in dimensions and shapes. Naturally, the pattern shape may be changed by changing the etching conditions such as the etching time and the gas flow rate.

Next, referring to FIG. 1(b), description will be given of an actual pattern measuring procedure. First, under a plurality of acquiring conditions beforehand designated in step S0003, an SEM image of the pattern to be measured is acquired. In this image acquisition, a semiconductor wafer in which a pattern to be measured is formed is first loaded in an SEM apparatus described later, and alignment and the like are conducted in advance and then an image is acquired at a desired position of the pattern to be measured (step S0010). Next, data matching is conducted between a set of SEM images taken under a plurality of different image acquiring conditions and the simulation library created in the procedure shown in FIG. 1(a) (step S0011).

By comparing each SEM image with a simulation waveform under an associated acquiring condition to select a simulation result for which the coincidence degree is comprehensively best, a shape and edge positions of the pattern to be measured are estimated. Next, based on the matching results between the SEM images and the library, the pattern shape and pattern dimensions desired by the user are calculated (step S0012). In the simulation waveforms in the library, the relationships between the waveforms and the edge positions are clearly known; hence, based on the matching results between the SEM images and the simulation waveforms, the pattern edge positions in the SEM image can be correctly estimated. Based on the estimated results of the pattern edge positions, the dimensions can be correctly measured. Finally, the measured results are output to a screen and a file (step S0013).

Next, description will be given of an embodiment of a pattern measuring apparatus with reference to FIG. 4. The left-side section of FIG. 4 shows an example of a representative SEM apparatus 010 to acquire SEM images used for the pattern measurement. A primary electron beam 012 emitted from an electron gun 011 is focused through a focusing lens 013 and an objective lens 015 to be radiated as quite a small spot onto a specimen 017. When the electron beam 012 is radiated, secondary electrons and reflected electrons are emitted from the radiated area according to the material and the shape of the specimen (electrons 018). Two-dimensional scanning of the primary electron beam 012 is conducted by use of a deflector 014, omitted electrons 018 are detected by a reflected electron detector 019 or a secondary electron detector 020 to be converted into electric signals, and the electron signals are converted through an A/D converter (not shown) into digital signals such that a converted two-dimensional digital images are memorized in respective image memories 031. As shown in the lower section of FIG. 4, the reflected electron detector 019 divided into four partitions of front, rear, left, and right partitions can separately detect the electrons emitted in the respective directions. Also, mesh-shaped electrodes 021 arranged on the lower side of the reflected electron detector and on the upper side of the objective lens can also vary the energy width of electrons to be detected. It is preferable to detect image signals under these different detecting conditions synchronously with one dose of the electron beam radiation.

In a case where the images are detected synchronously with one dose of the electron beam radiation, in the images under these different detecting conditions, data of the same pixel coordinates are image data at the same position on the pattern to be measured; hence, the positional alignment among a plurality of images of the different detecting conditions is not required. Further, since the SEM apparatus of FIG. 4 has an inclinable stage, it can also acquire SEM images in different directions. Images of different stage inclination angles cannot be simultaneously acquired; hence, in such a case, the positional alignment is conducted among the images. As for the image acquiring conditions, as well as the detectors and the specimen stage shown in FIG. 4, an amount of the energy or current, a radiation direction, or the like of the electron beam to be radiated may be changed; and all of these functions are not necessarily required.

The SEM apparatus 010 is controlled by a control unit 033 in an overall control and image processing section 030, and the acquired images are stored in the image memories 031 together with respective images acquiring conditions. It will be assumed below that, when simply expressing an SEM image, the SEM image is a generic term for the images acquired under these various conditions. The matching processing is executed between these SEM images and the simulation waveforms which correspond to the respective image acquiring conditions and which are memorized in the library 001, to conduct the pattern shape estimation and the dimension measurement. The matching processing is executed by an image processing unit 032. The matching processing may be once stored via an external interface 034 in an external storage (not shown) and then executed by an external computer. In a storage medium of the external computer, a program to execute processing, which will be described in conjunction with the present embodiment and the following embodiments, has been memorized; and based on a signal transmitted from an SEM or the like, the computer is caused to execute the processing which will be described below.

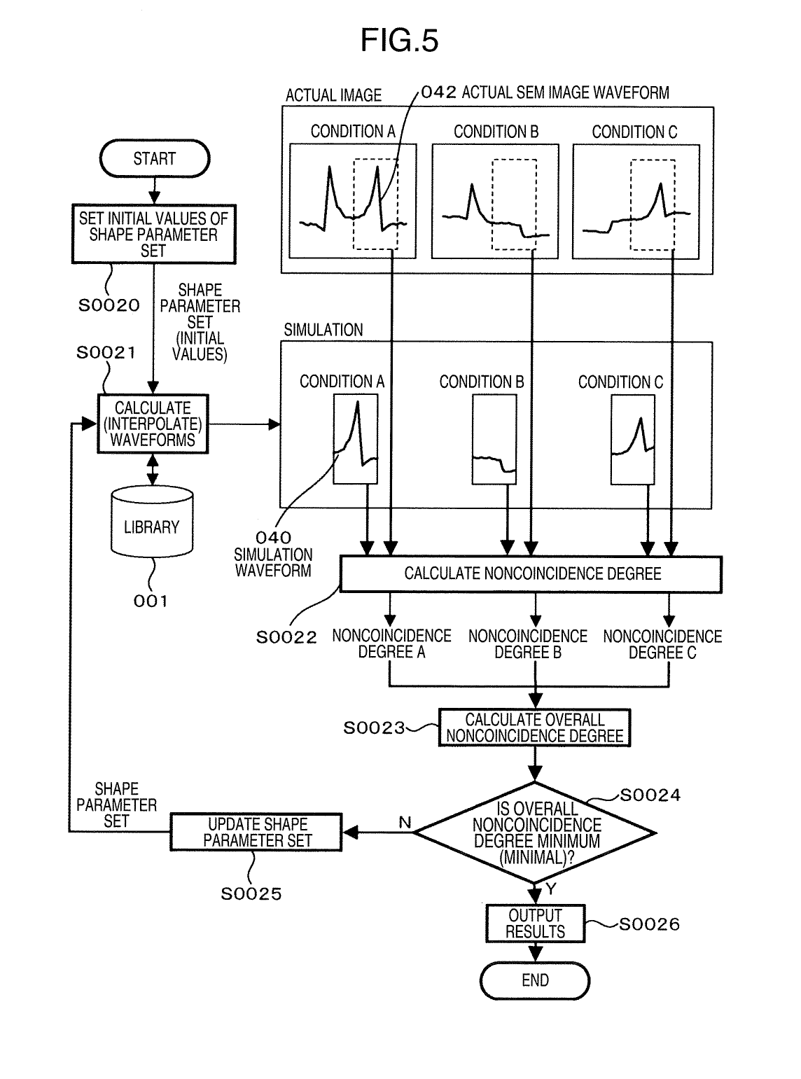

Next, description will be given in detail of the matching method between a plurality of images acquired under different acquiring conditions and associated simulation waveforms with reference to FIG. 5. As described above, the library 001 stores SEM simulation waveforms and inputs therefor or pattern shape parameters with a relationship therebetween; by inputting shape parameters, a simulation result of an SEM signal waveform can be obtained corresponding to the shape. According to the pattern measuring method of the present invention, by using the simulation library to quantitatively evaluate the coincidence degree between a waveform profile of an actual SEM image as the measurement target and a simulation profile, the matching is implemented.

FIG. 5 is a flowchart showing in detail the waveform matching process. The library creation (FIG. 1(a)) and the SEM image acquisition S0010 under each condition are beforehand conducted. First, an initial shape is set for the matching (S0020). For the initial shape, for example, average values of shape parameters in the library may be set. Or, naturally, the initial value setting method using image feature amounts described in Patent Literature 2 may be employed.

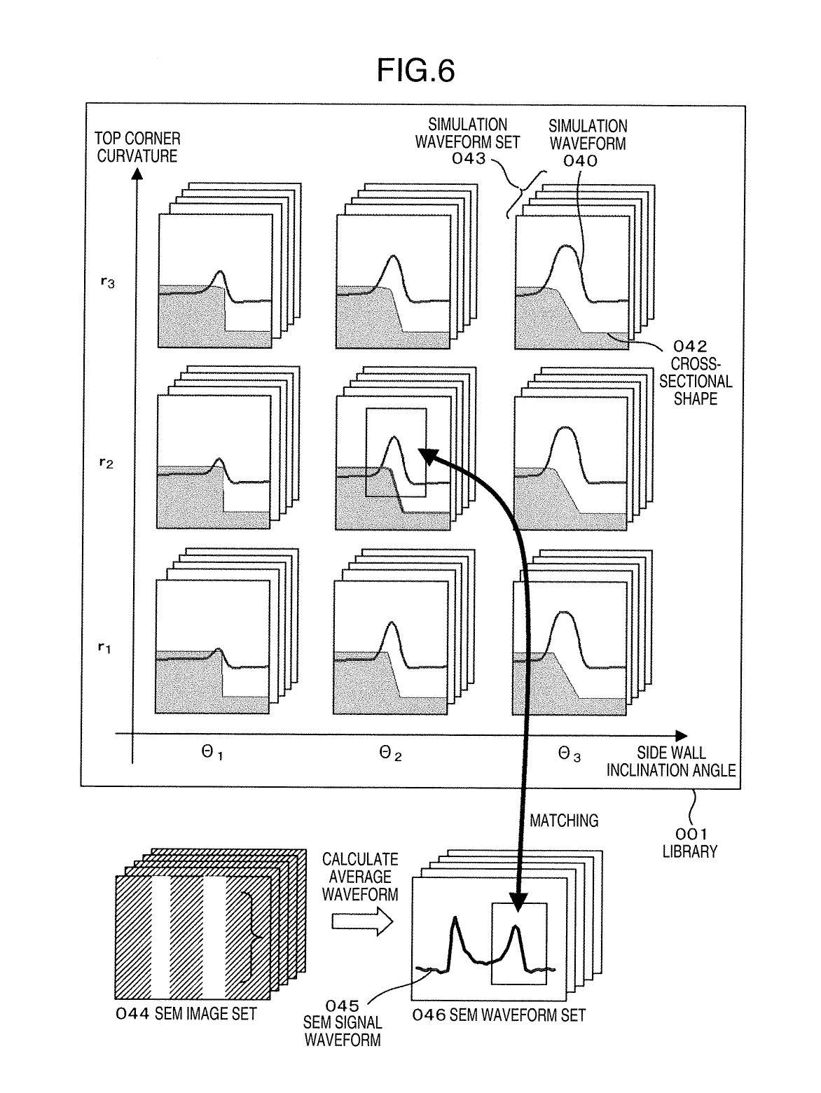

Next, by referring to the library 001, a simulation waveform 004 is calculated under each acquiring condition for the initial value in the shape parameter set beforehand set (S0021). FIG. 5 shows examples of images acquired under three kinds of conditions; however, it goes without saying that, the measurement is similarly possible under two kinds of image acquiring conditions as well as under four or more kinds thereof. The library will be described in detail later with reference to FIG. 6. Next, the noncoincidence degree is calculated between the calculated simulation waveform 040 and the actual SEM signal waveform 041 of the pattern to be measured acquired under each condition by the SEM apparatus. The calculation of the noncoincidence degree is first conducted under each condition (S0022), and then, by an operation of the results, the overall noncoincidence degree is calculated (S0023).

An average of the noncoincidence degrees under the respective image acquiring conditions may be used as the operation of the noncoincidence degrees. In the calculation of the noncoincidence degree for the waveform under each condition (S0022), for example, the difference in the signal value is calculated between a cross-sectional shape 042 and the simulation waveform 040, and the square sum thereof for all profiles can he calculated as the noncoincidence degree between the actual waveform and the simulation waveform. Next, by averaging the noncoincidence degrees, the overall noncoincidence degree is calculated. When such a simulation waveform set is calculated by use of data in the library that the overall noncoincidence degree is minimum, namely, the coincidence degree is the highest, the cross-sectional shape input for the waveform simulation set becomes the estimation result of the actual pattern cross-sectional shape.

So, it is judged whether or not the overall noncoincidence degree is minimum (S0024); and if the degree is not minimum, the shape parameter set is updated (S0025), and a waveform is again calculated for the new shape (S0021) to execute the matching processing (S0022 to S0024), and the processing is repeatedly executed until it is determined that the overall noncoincidence degree is minimum. When the shape parameters for which the noncoincidence degree is minimum are finally determined, the result is output (S0026) and then the matching processing is terminated.

Here, the operation is repeatedly conducted so that the overall noncoincidence degree becomes minimum; however, the minimum value is not actually known; hence, a minimal value in the parameter space is judged. These matching operations can be implemented by applying a general nonlinear optimization scheme such as the Levenberg-Marquardt method.

Next, description will be given further in detail of the library and the calculation of the noncoincidence degree with reference to FIG. 6. As shown in FIG. 6, in the library 001, sets 043 are recorded, each set including a simulation cross-sectional shape 042 and its associated SEM simulation waveforms 040 under various acquiring conditions. In order to explain a concept, FIG. 6 shows waveforms and pattern cross-sectional shapes; however, the simulation data is expressed by numeric data strings, and the cross-sectional shapes are expressed by shape parameters stored in the library. FIG. 6 is a library configuration example to measure a pattern in a process in which the side wall inclination angle θ and the top corner curvature of the pattern mainly change. The changing shapes are so important for the process control as to be measured; hence, by assuming these as shape parameters, the simulation is conducted by use of a plurality of different parameters of the shape range set in advance (step S0002), to create the library.

In FIG. 6, to explain a concept of the shape parameter space, two shape parameters of the side wall inclination angle 0 and the top corner curvature R are represented along the x and y axes, respectively. The simulation is carried out by use of a pattern cross-sectional shape determined by a combination of these shape parameters. This example represents for simplicity three kinds of the side wall inclination angle θ and the top corner curvature R, respectively; however, actually, the simulation is beforehand conducted within the range covering the pattern shapes which may take place due to the process change, finely so as to cope with the precision for the measurement.

Here, the shape parameters of the simulation data are discrete values; however, by interpolation between the simulation data, it is possible to estimate a simulation waveform using a shape parameter for which no simulation result is present. A method may be employed for the simulation waveform interpolation, the method being disclosed in, for example, J. S. Villarrubia, A. E. Vladar, J. R. Lowney, and M. T. Postek, “Edge Determination for Polycrystalline Silicon Lines on Gate Oxide,” Proc. SPIE 4344, pp. 147-156 (2001).

Further, FIG. 6 shows an example of only the side wall inclination angle and the top corner curvature for simplicity; however, naturally, data obtained by changing the bottom corner curvature of the pattern and the distance to an adjacent pattern may also be included in the library (in this case, a multidimensional space of more than three dimensions).

Here, for the simulation waveform 040, only one of the right and left edges may be calculated as shown in FIG. 6 (only the right edge is calculated in FIG. 6). In the matching, the simulation signal may be reversed between right and left depending on the matching target pattern direction if necessary. Here, the SEM simulation is carried out under a plurality of conditions associated with the SEM apparatus 010 shown in FIG. 4.

In the measuring, a plurality of SEM images beforehand designated are taken by the SEM apparatus 010 to acquire an SEM image set 044. Next, SEM signal waveforms 045 are calculated from SEM images to be compared with the simulation waveform set 043. At this time, if a pattern of a line shape is obtained as shown in FIG. 5, averaging adjacent image data to calculate an average waveform profile enables removing signal noise and stably measuring. As shown in FIG. 5, after calculating an SEM waveform set 046 of associated waveform profiles from the SEM image set 044 under the respective acquiring conditions, the matching is carried out between the respective SEM signal waveforms 045 and the associated simulation waveforms 043 to select a simulation waveform set, so that the coincidence degree between the actual SEM waveform and the simulation waveform set becomes the highest.

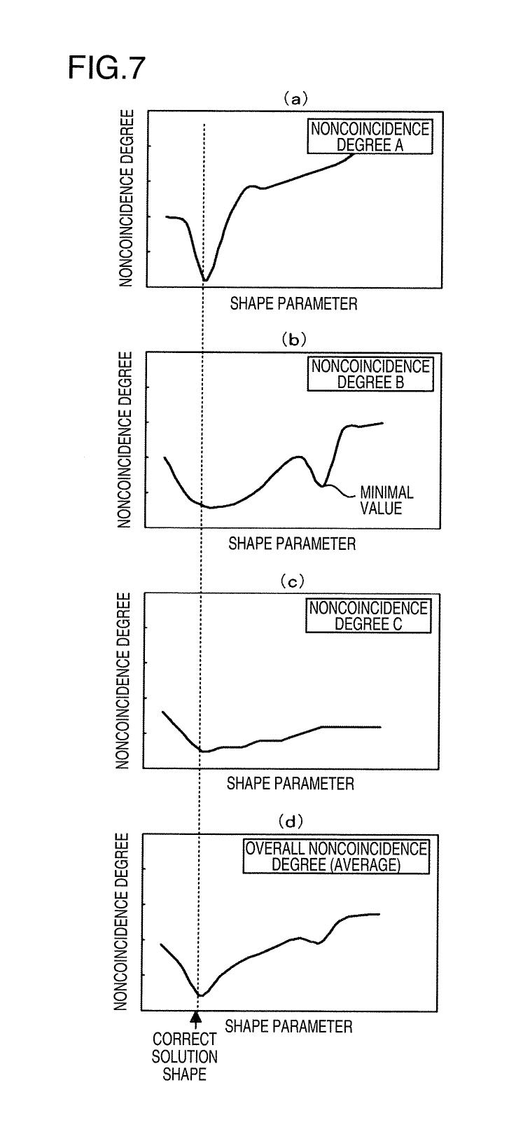

Next, referring to FIG. 7, description will be given of an example of the changeing noncoincidence degree with respect to shape parameters and an advantage by using images acquired under a plurality of different conditions of the present invention. As shown in FIG. 5, the calculation of the noncoincidence degree between an actual waveform and a simulation waveform is conducted for each image acquiring condition. FIGS. 7(a), (b), and (c) respectively show calculation results of the noncoincidence degree under three different image acquiring conditions, and (d) shows an average value thereof, namely, an example of the overall noncoincidence degree.

The horizontal axis represents shape parameters associated with a simulation library waveform, and the vertical axis represents, for each simulation waveform, calculation results of the noncoincidence degree obtained in the matching with an SEM signal waveform of a pattern having a certain shape. FIG. 7 shows an example using one shape parameter for simplicity; however, actually, there is employed a multidimensional space having as many axes as the kinds of shape parameters used when creating simulation library (in the example of FIG. 6, three-dimensional space with two shape parameters). The space including the noncoincidence degree and the shape parameters will be referred to as a space of the noncoincidence degree hereinbelow. The change in the noncoincidence degree with respect to the shape parameters is determined by the sensitivity of the SEM image to the target shape change. If the image is sensitive to the pattern shape change, the noncoincidence degree lowers only when the pattern shapes match each other. In this case, the noncoincidence degree takes the minimum value only for one shape parameter, for example, as shown in FIG. 7(a); and the noncoincidence degree abruptly lowers in the periphery of the correct solution. For an SEM image having such characteristic of the space of the noncoincidence degree, it is possible to conduct stable and correct shape estimation; however, such favorable relationship cannot be necessarily always obtained. For example, in the example of FIG. 7(b), a minimal value is present in addition to the correct solution; hence, there exists high possibility to select the wrong shape parameter as the solution.

Further, in the example of FIG. 7(c), the change in the noncoincidence degree is small with respect to the change in the shape parameter, and the change is smooth in the periphery of the minimum value. In this case, it is feared that the estimation result is not stabilized. The characteristic of the noncoincidence degree varies depending on a combination of the image acquiring condition and a kind of the shape parameter; hence, when the shape (correct solution shape) of the pattern to be measured changes, it is feared that the acquiring condition of the image having the optimal characteristic changes. So, in this way, according to the present invention, combining SEM images having different characteristics prevents the deterioration in the matching precision.

As shown in FIG. 7(d), when the overall noncoincidence degree is calculated by averaging the noncoincidence degrees obtained by use of a plurality of images, the characteristic of the space of the noncoincidence degree is lower than that of (a), but is improved compared with that of (b) and (c). In this way, in the above pattern measuring method, combining images having different characteristics to use in the measurement enables lowering the influence from local solutions other than the correct solution to obtain stable matching results on average. As a result, it is possible to conduct stable high-precision measurement of pattern shape and dimensions.

As described with reference to FIGS. 1 to 6, in the above pattern measuring method, comparing with the SEM simulation waveform enables measuring with high precision so as to consider physical phenomena associated with electron beam radiation such as influence from scattering of electrons inside and outside the pattern to be measured and influence from the cross-sectional shape of the pattern. In addition, by using a plurality of different image acquiring conditions, the sensitivity to the change in the SEM image with respect to the pattern shape change is comprehensively improved; hence it is possible to conduct stable high-precision measurement for a pattern shape change to which the sensitivity cannot be obtained by use of a conventional SEM image acquired under one kind of conditions.

Incidentally, in each noncoincidence degree calculation process in the matching, it is also possible to set a predetermined judgment threshold value for the noncoincidence degree set beforehand and to add a step for judging, as a warning or an error, a case where the noncoincidence degree is more than a fixed value and there exists an SEM image. At occurrence of an error, by displaying an SEM image having a high value of the noncoincidence degree, its waveform profile, and a simulation waveform as a result of the matching on the screen at a time, the operator can easily recognize the abnormality. Adding such error judgement processing enables implementing stable measurement with higher reliability.

In place of the noncoincidence degree, the coincidence degree may also be used as the reference to output, as a result, a solution for which the coincidence degree is maximum (maximal). It is also possible that the result output is not only the solution of the maximum or minimum value, but also, for example, n higher-order candidates (n is a natural number equal to or more than two); or, the shape may also be selected from a plurality of candidates by using a different estimation method. In detecting the overall noncoincidence degree, if there exists any determination reference (waveform acquiring condition) to be given importance into consideration, the overall noncoincidence degree may also be determined after weighting other comparison targets.

### Embodiment 2

Next, description will be given of an example of the matching method other than that of the second embodiment. In the first embodiment, the matching is conducted by use of the overall noncoincidence degree which is an average value of noncoincidence degrees under the respective conditions. As the second embodiment, another matching method is disclosed. In the second embodiment, the matching processing similar to that executed for the overall noncoincidence degree in the first embodiment is executed only for the noncoincidence degree under each image acquiring condition, and the pattern shape and dimensions are estimated based on the consistency between the images of the noncoincidence degrees.

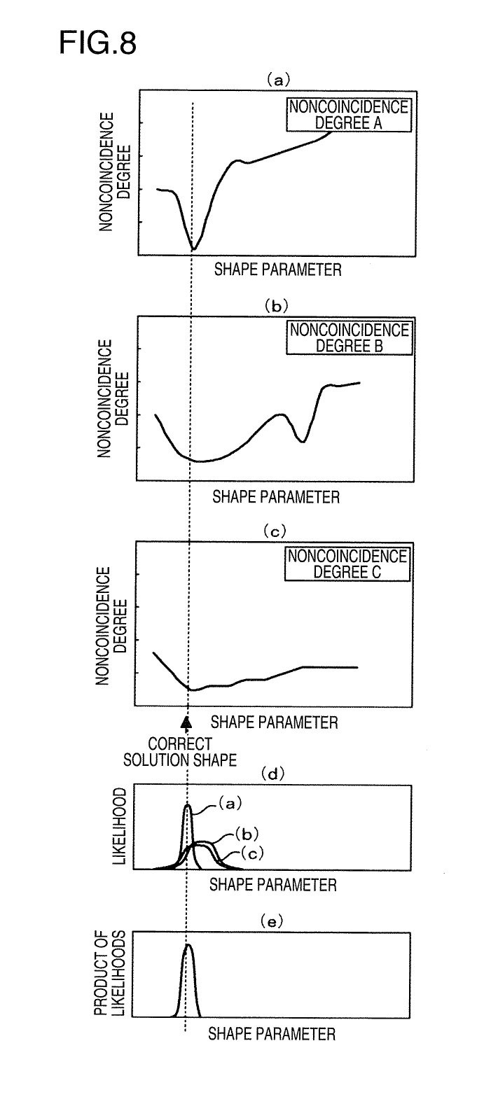

First, the matching is conducted for the respective images to calculate a shape parameter set with respect to which a noncoincidence degree under each image acquiring condition takes a maximum value or a minimum value and a second differential in each parameter direction of the noncoincidence degree in the periphery of the minimum value. The second differential of the noncoincidence degree in the estimation result of the shape parameter indicates steepness of the change in the noncoincidence degree at the point. For example, in the space of the noncoincidence degree as shown in FIG. 8, (a) has the largest value of the second differential among (a), (b) and (c). As the change in the noncoincidence degree is steeper at the periphery of a minimal value, it is more probable that the shape parameter is the correct solution; and when the change is smooth, it is highly probable that the periphery thereof is also the solution.

So, in the second embodiment, the likelihood of the solution in the periphery of a minimal value is represented by use of a normal distribution having dispersion associated with the value of the second differential. FIG. 8(d) shows a calculation result of the likelihood of the matching result for each image; the likelihood for a steeper minimal value or a larger second differential is calculated from a normal distribution having smaller dispersion. In this way, the likelihood is calculated for each image acquired under each condition, and a shape parameter at which the product of the likelihoods has a maximum value (FIG. 8(e)) may be determined as the solution.

When the calculation of the second embodiment is employed, there may be a case where a product of the likelihoods is zero in any image. In this case, a minimal value other than the correct solution is selected, and it can be considered that this is the case where no overlap section exists between the results obtained under the respective conditions. In such a case, the nearness among the likelihood peak positions is evaluated, and if there exists a faraway minimal value, the calculation may be again conducted by eliminating the image of the acquiring condition. Or, when the image for which the peak position is far away has a large value of the noncoincidence degree, it is also effective for the implementation of highly reliable measurement, to display a warning indicating absence of the overlap section or to perform error processing. Also, as another method using the second differential, naturally, an estimation result obtained by use of an image for which the second differential is maximum may be used as the correct solution without calculating the likelihood.

In this way, other than the first embodiment, calculating the noncoincidence degree between an SEM image and a simulation waveform for each of the SEM images acquired under a plurality of mutually different acquiring conditions, and the matching by comprehensive use of the calculated results based on the consistency thereof can also produce advantageous effects similar to ones of the first embodiment.

### Embodiment 3

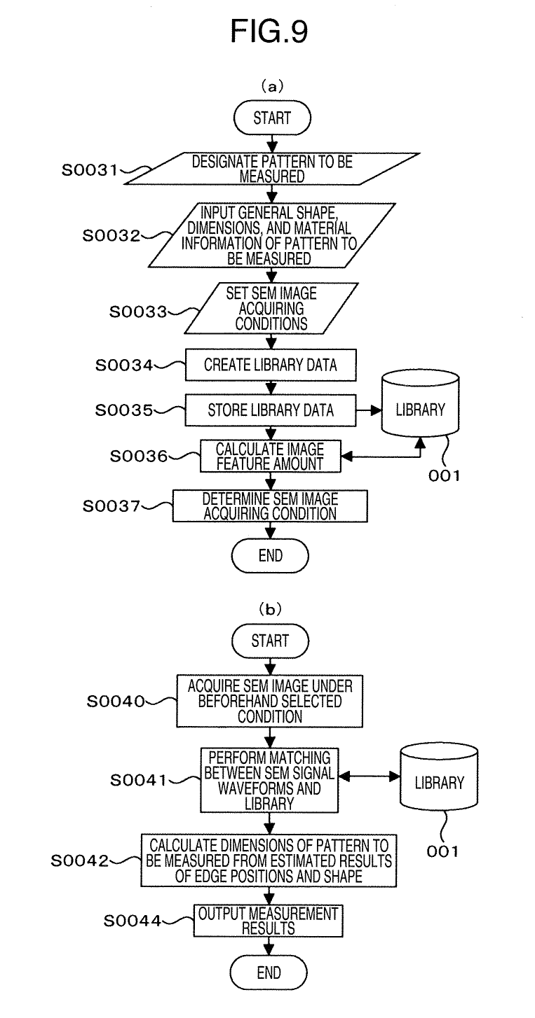

In the first and second embodiments, the matching is conducted by comprehensive use of SEM images acquired under a plurality of mutually different acquiring conditions. On the other hand, as the third embodiment, another method is disclosed, the method comprising: selecting an optimal image acquiring condition using SEM simulation waveforms beforehand acquired under various acquiring conditions. FIG. 9 shows a processing flow. First, as in the first embodiment, the operator designates a pattern to be measured (S0031) and inputs information on the general shape, dimensions, and material of the designated pattern to be measured (S0032).

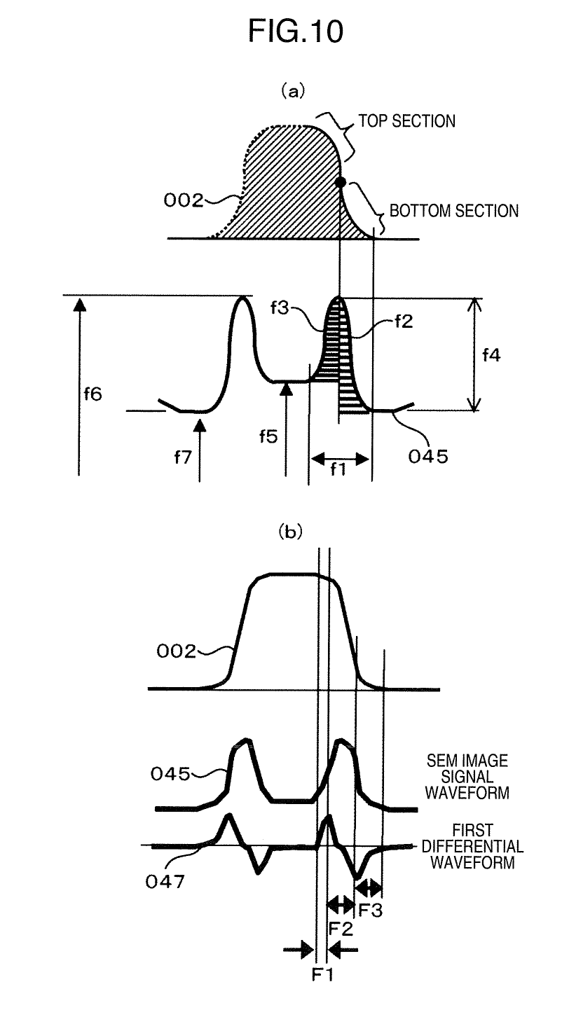

Next, the operator sets an image acquiring condition used in the measurement (S0033). Incidentally, in the third embodiment, the image acquiring conditions at the time of actual measurement are some of the conditions in this step; hence, the operator may set relatively many conditions without paying attention to whether or not images can be simultaneously acquired. Next, library data is created by conducting simulation associated with the set image acquiring conditions (S0034), to store the result in the library 001 with a relationship between the result and the pattern shape information (S0035). Next, the image feature amount to determine an appropriate image acquiring condition for the shape and dimension measurement is calculated for each simulation waveform in the library 001. The image feature amount is used to quantize a change in the SEM signal waveform taking place due to difference in the pattern shape. FIG. 10 shows an example of image feature amounts to be used for the pattern measuring method.

In FIG. 10(a), Feature Amount f1 is width of the edge peak section (referred to as a white band hereinbelow). The white band width is a feature amount reflecting the width of the edge section viewed vertically from above. Feature Amount f2 is average width of an outer section of the white band section relative to the peak position and is a feature amount reflecting the magnitude of the curvature of the bottom section. Feature Amount f3 is average width of an inner section of the white band section relative to the peak position and is a feature amount reflecting the magnitude of the curvature of the top section.

Feature Amount f4 is the magnitude of signal intensity and is a feature amount reflecting the magnitude of the taper angle as shown in FIG. 10. Further, in a system capable of evaluating the absolute signal amount, it is possible to use absolute signal amount f6 of the peak section and minimum absolute signal amount f7 of the outer side of the edge. f6 changes depending on the taper angle due to the inclination angle effect, and f7 changes depending on the space. FIG. 10(b) shows another example of feature amounts. By using the first differential of the edge peak section, distances among points where the first differential takes an extremal value and where the first differential is zero are set as feature amounts F1, F2, and F3. F1 is a value changing according to the curvature of the top corner, F2 correlates with the side wall inclination angle, and F3 correlates with the falling section.

As above, the various image feature amounts as shown in FIGS. 10(a) and (b) vary according to the pattern shape; hence, it is considered that an image for which these image feature amounts greatly vary is sensitive to the pattern shape change. So, in the third embodiment, the image feature amount is calculated for the SEM simulation waveforms in the library to select, based on the calculation results, an SEM image acquiring condition sensitive to the shape change, and then an image for measurement is acquired based on the selected condition.

Preferably, the image for which a pattern shape can be stably estimated by use of an SEM image is an image for which the one-to-one correspondence can be established between the image feature amount and the shape parameter. So, an image may be selected, for which, in the shape parameter space of the library, the difference between the maximum value and the minimum value of the calculated image feature amount is large and its change is monotonously increases/decreases with respect to the shape parameter. For example, presence or absence of the extremal value of the change in the image feature amount with respect to a shape parameter may be set as the evaluation index for the evaluation of the monotonicity. In this way, based on the evaluation results of the image feature amount of the simulation waveform, there is determined an image acquiring condition sensitive to the shape change to be measured (FIG. 9(a) S0037).

There may be used one image acquiring condition or a plurality of image acquiring conditions. If there exists a condition particularly better than other conditions, one condition is sufficient; if the conditions are similar to each other, the condition may be determined considering image acquiring easiness or the like. For example, if it can also be presented whether or not simultaneous image acquisition is possible, it is helpful for the operator to select an appropriate condition. For example, it is preferable that, when several image acquiring conditions are selected, the time period required to acquire an image is displayed.

In the measurement, an SEM image is acquired under the acquiring condition selected in step S0037; thereafter, as in the first embodiment, the matching is conducted between the acquired image and the simulation waveforms in the library (S0041) to calculate a measurement result from the matching result (S0042), and then the result is output (S0044). When only one image acquiring condition is selected, the matching processing may be ordinarily executed by use of the noncoincidence degree between the acquired image and the simulation waveforms.

In this way, by employing the third embodiment, the measurement can be carried out by selecting only SEM images having a characteristic sensitive to the shape change; hence, the high-precision measurement similar to that of the first and second embodiments can be conducted by the less image acquisition. This can shorten the time period required for the image acquisition; further, the data processing amount for the measurement is also reduced and the operation time period can be accordingly reduced. Incidentally, in the third embodiment, the image feature amount is used to select the image acquiring condition; however, the characteristic of the noncoincidence degree may be calculated to select it as shown in FIG. 7. AT this time, quite a long calculation time is required to conduct the calculation for all image acquiring conditions and all shape parameters. So, for example, calculating the noncoincidence degree between an average shape in the library and waveforms of shapes other than the average shape enables high-speed processing.

### Embodiment b 4

In the third embodiment, the image acquiring conditions are evaluated by use of the image feature amount of the SEM simulation waveforms to select an image acquiring condition based on the evaluation results. Using the evaluation results under the image acquiring conditions of the third embodiment enables improving the matching sensitivity to the overall noncoincidence degree of the first embodiment. In the first embodiment, the overall noncoincidence degree is obtained as an average of the noncoincidence degrees calculated for the respective images; in the average calculation, conducting weighted average by adding weights based on the evaluation results of the image acquiring conditions enables preferentially using information on an image under a sensitive acquiring condition; hence, it is possible to improve the library matching precision and the pattern shape and dimension measuring precision.

For example, if it is desired to obtain high sensitivity to information on concavity and convexity on a surface such as the top corner curvature and the bottom corner curvature, a larger weight may be assigned to an image acquired by a relatively lower acceleration electron beam which produces much information on concavity and convexity. Also, if it is desired to increase measuring sensitivity to the shape change of the bottom section of a deep groove or hole structure, a larger weight may be assigned to electrons emitted with high energy which easily reflect information on the bottom section of the pattern.

The pattern measuring technique as described above is applicable to any target for which the image acquisition and the simulation can be conducted by an electron microscope or a charged particle beam apparatus similar thereto. Further, although description has been given of the measurement of semiconductor patterns, the technique is also applicable to MEMS and fine industrial parts.

### REFERENCE SIGNS LIST

001 Library
002 Line pattern (cross-section)
003 Secondary electron signal
004 Reflected electron signal (left)
005 Reflected electron signal (right)
010 SEM apparatus
011 Electron gun
012 Electron beam
013 Focusing lens
014 Deflector
015 Objective lens
016 Specimen stage
017 Specimen
018 Electrons
019 Reflected electron detector
020 Secondary electron detector
021 Electrode
030 Overall control and image processing section
031 Image memory
032 Image processing unit
033 Control unit
034 External interface
040 Simulation waveform
041 Actual SEM signal waveform
042 Cross-sectional shape
043 Simulation waveform set
044 SEM image set
045 SEM signal waveform
046 SEM waveform set
047 SEM signal first differential waveform

1. A pattern shape selection method for selecting a pattern by referring, with respect to waveform information obtained based on scanning a charged particle beam onto a specimen, to a library in which waveform information is registered for each shape of a plurality of pattern shapes, wherein the method comprises:
obtaining, based on radiation of a charged particle beam onto a specimen, plural pieces of waveform information under a plurality of waveform acquiring conditions;
selecting pattern shape information memorized in the library, by referring, with respect to the plural pieces of waveform information, to a library memorizing waveform information obtained under different waveform acquiring conditions for each of a plurality of pattern shapes.

2. A pattern shape selection method according to claim 1, characterized in that the library memoires the pattern shape information and a plurality of waveforms under a plurality of waveform acquiring conditions with a relationship therebetween.

3. A pattern shape selection method according to claim 2, characterized in that the plurality of waveform acquiring conditions include a radiation condition of a charged particle beam, a detecting condition of charged particles, an image processing condition based on detection of charged particles, a specimen condition, or a combination thereof.

4. A pattern shape selection method according to claim 1, characterized in that, when referring to the library with respect to the plural pieces of waveform information, the pattern shape information is selected based on overall coincidence degrees or noncoincidence degrees with respect to the plural pieces of waveform information memorized in the library.

5. A pattern shape selection method according to claim 1, characterized in that the pattern shape information memorized in the library is numeric data of a modeled pattern shape.

6. A pattern shape selection method according to claim 5, characterized in that the waveform information memorized in the library are obtained based on electron microscope simulation using the modeled numeric data of the pattern shape and a plurality of waveform acquiring conditions.

7. A pattern shape selection method according to claim 6, characterized in that the modeled numeric data is set as a plurality of different input parameters corresponding to a measuring range of the pattern.

8. A pattern shape selection method according to claim 7, characterized in that, when referring to the library with respect to the plural pieces of waveform information, the input parameters for which the overall coincidence degree or noncoincidence degree of the waveform shape takes a minimum value are obtained.

9. A pattern shape selection method according to claim 8, characterized in that, when referring to the library with respect to the plural pieces of waveform information, consistency of the input parameters is judged.

10. A pattern shape selection method according to claim 8, characterized in that sensitivity of a change in a simulation waveform to the input parameters is evaluated and a waveform acquiring condition whose sensitivity takes a highest value is selected from the waveform acquiring conditions.

11. A pattern measuring apparatus for selecting a pattern shape by referring to a library memorizing waveform information created based on charged particles emitted from a specimen and pattern shapes with a relationship therebetween, characterized by comprising:
obtaining, based on radiation of a charged particle beam onto a specimen, plural pieces of waveform information under a plurality of waveform acquiring conditions;
selecting pattern shape information memorized in the library, by referring, with respect to the plural pieces of waveform information, to a library memorizing waveform information obtained under different waveform acquiring conditions for each of a plurality of pattern shapes.

12. A pattern measuring apparatus according to claim 11, characterized in that the library memoires the pattern shape information and a plurality of waveforms under a plurality of waveform acquiring conditions with a relationship therebetween.

13. A pattern measuring apparatus according to claim 12, characterized in that the plurality of waveform acquiring conditions include a radiation condition of a charged particle beam, a detecting condition of charged particles, an image processing condition based on detection of charged particles, a specimen condition, or a combination thereof.

14. A pattern measuring apparatus according to claim 11, characterized in that, when referring to the library with respect to the plural pieces of waveform information, the pattern shape information is selected based on overall coincidence degrees or noncoincidence degrees with respect to the plural pieces of waveform information memorized in the library.
